(19) United States
(12) Patent Application Publication
(10) Pub. No.: US 2010/0060297 A1
(43) Pub. Date: Mar. 11, 2010

(54) ELECTRODE ARRANGEMENT FOR GENERATING A SIGNAL INDICATIVE FOR THE PRESENCE OF AN OBJECT WITHIN AN OBSERVATION REGION

(76) Inventor: Hans Schwaiger, Muenchen (DE)

Correspondence Address: K.F. ROSS P.C., 5683 RIVERDALE AVENUE, SUITE 203 BOX 900, BRONX, NY, 10471-0900, US

(21) Appl. No.: 12/447,476

(22) PCT Filed: Aug. 20, 2008
(86) PCT No.: PCT/EP08/06859

§ 371 Date: Apr. 28, 2009

(30) Foreign Application Priority Data
Aug. 20, 2007 (DE) 102007039162.7

(51) Int. Cl. G01R 27/26

(52) U.S. Cl. 324/658

(57) ABSTRACT

The invention relates to an electrode arrangement for achieving the detection of the presence, position, and/or the intrusion of an object, particularly of human limbs in an observation region. The aim of the invention is to provide solutions that are advantageous over prior solutions when detecting an object, especially a living body that is approaching a detection system. Said aim is solved, according to the invention, by an electrode arrangement for detecting the presence of an object within an observation region, with an electrode device for emitting an alternating field into an emission range, an electronic circuit for applying an alternating voltage to the electrode device, a connecting line for connecting the electrode device to the electronic circuit, and a device for shielding the connecting line. Said electrode arrangement is characterized in that an electrode-testing device is provided for generating a signal indicating the continuity of the electrode device.

The invention is based on an electrode arrangement for carrying out the detection of the presence, position, and/or the penetration of an object, especially by human limbs, in or into an observation area. The invention, in this respect, is especially based on an electrode arrangement, through which this detection takes place on the basis of field-electric reciprocation effects.

Proximity and contact sensors are known in which a detection of the presence of human limbs is carried out on the basis of the field-electric reciprocation effects. An electrical property of the human body is significant in this respect, which consists in that the conductive body near a detection electrode influences their capacity. The capacity of the detection electrode is definitive for the sensor signal in the known detection systems.

The proximity can be detected via frequency or phase measurement.

A problem in connection with this is the necessary sensitivity and interference resistance of the process for certain uses. In the case of the detection of one of the smallest body parts, such as e.g. a finger, typically only small variations in capacity from 0.01 to 0.1 pF result, which still have to be recognized for the realization of a protective system. The acquirable sensitivity in the process of frequency measurement is determined in the process by the relative variations in capacity as opposed to the basic capacity of an oscillator, which is usually as small as possible, which in turn means a high frequency of oscillation, which can be critical not only with regard to the EMC problem but also to extrinsic interfering voltages.

The invention is based on the task of specifying solutions through which advantages result as opposed to previous proposals, in the detection of the proximity of an object, especially of an animated body, to a detection system.

This task is resolved according to the invention by an electrode arrangement for detecting the presence of an object in an observation area with:
an electrode device for issuing an alternating field into an issuing zone,
an electronic circuit for charging the electrode device with an alternating voltage,
a connecting cable for connecting the electrode device to an electronic circuit, and
a shield device for shielding the connecting cable,
   characterized by an electrode checking device for generating an indicative signal with regard to the electric continuity of the electrode device.

This electrode arrangement makes it possible to ascertain potentially defective states of the electrode device and thereby to guarantee that a failure of the detection incidences is not to be singularly traced back to a defective electrode structure. It is possible to undertake a system calibration by means of the measured electric continuity.

Advantageous embodiments of this electrode arrangement are dealt with by the sub-claims.

According to a further aspect of the present invention, the task stated at the start is also is resolved by an electrode arrangement for detecting the presence of an object in an observation area, and with an electrode device for issuing of an alternating field into an issuing zone, an electronic circuit for charging the electrode device with an alternating voltage, in which this electrode arrangement stands out in that the electrode device comprises several transmission electrode sections which are each attached via a connecting cable to the electronic circuit, in which the connecting cables are each supplied with a shield and the transmission electrode sections are exposed in a staggered way.

Advantageous embodiments of this electrode arrangement are also dealt with by the corresponding sub-claims.

According to a further aspect of the present invention, the task stated at the start is also resolved by an electrode arrangement for detecting the presence of an object in an observation area, with an electrode device for issuing an alternating field into an issuing zone, an electronic circuit for charging the electrode device with an alternating voltage, a connecting cable for connecting the electrode device to the electronic circuit, and a shield device for shielding the connecting cable, in which this electrode arrangement stands out in that the electrode device and the shield device are effected as a flat conductor structure.

Further details and features of the invention come from the following description in conjunction with the drawing. It shows:

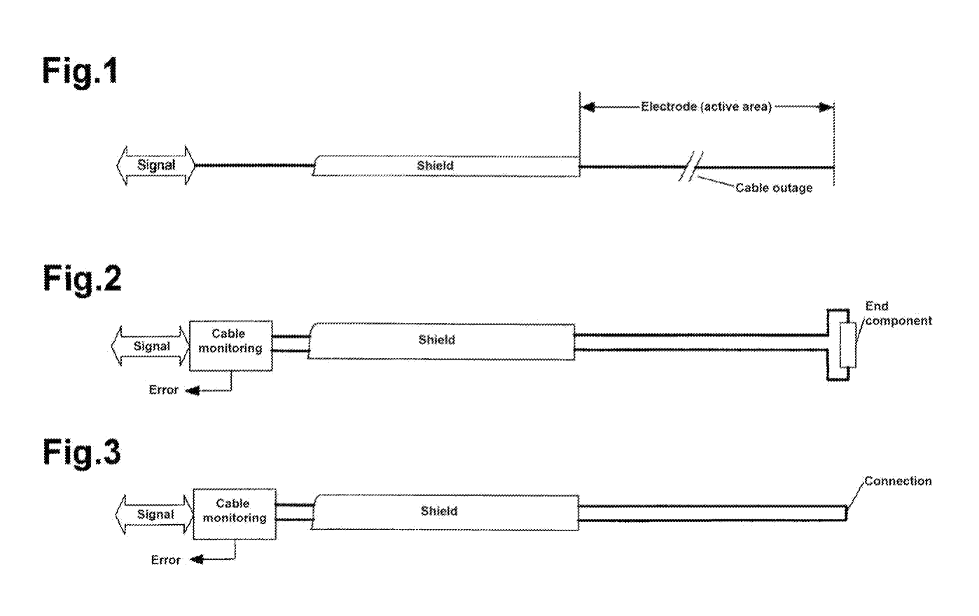

FIG. 1 a simplified representation by way of illustration of the structure of an electrode device for issuing an alternating field into an issuing zone, in which an electrode checking device is attached to this electrode device for generating an indicative signal with regard to the electric continuity of the electrode device;

FIG. 2 a simplified representation of an electrode device which comprises an up-and-down line section, in which the electric continuity of the electrode device is detected by means of an electric circuit including the up-and-down line section and a terminator circuit is provided in a transient area between the up-and-down line section;

FIG. 3 a simplified representation of an electrode device which comprises an up-and-down line section, in which the electric continuity of the electrode device is detected by means of a circuit including the up-and-down line section;

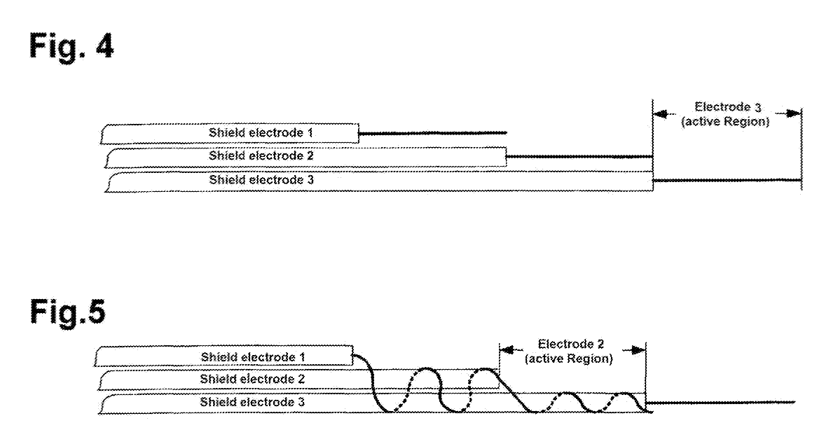

FIG. 4 a simplified representation of an electrode device which comprises several transmission electrode sections, in which these transmission electrode sections form a component part of a compact cable and are exposed in a staggered way in the longitudinal direction of this cable;

FIG. 5 a simplified representation of an electrode device that comprises several transmission electrode sections similar to the variant according to FIG. 4, in which these transmission electrode sections form a component part of a compact cable and are exposed in a staggered way in the longitudinal direction of this cable and moreover are wound around the cable in these exposed sections;

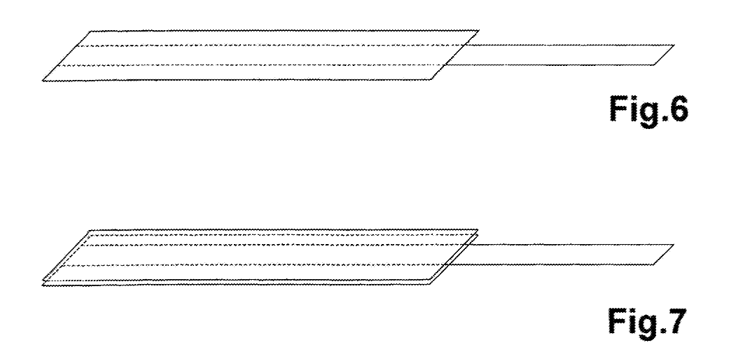

FIG. 6 a simplified representation by way of illustration of a unilaterally shielded flat electrode device;

FIG. 7 a simplified representation by way of illustration of a flat electrode device shielded on both sides;

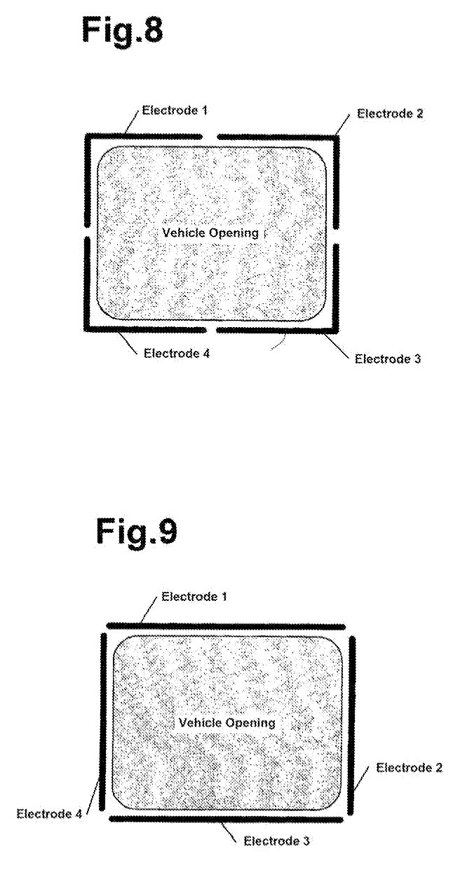

FIGS. 8 to 9 scheme representations by way of illustration of the disposition of the exposed electrode devices in the area of potential pinch-off edges of a vehicle window.

In the electrode arrangement represented in the FIGS. 1 to 3, the active area of the electrodes is not executed as a shielded electric conductor. A cable monitoring device is integrated into the system for detecting a cable outage. The cable monitoring can especially take place according to the following processes:
Measuring the electric runtime and signal reflection on the conductor (reflection at the breakpoint) (FIG. 1)
Electrodes executed with a bidirectional path. (FIG. 2)
An electronic component is situated in series at any location in the bidirectional path. (FIG. 3)

The electrical property of the disposition is altered by a cable outage and detected by the cable monitoring circuit. The measurement current can be a direct current, alternating current or an undulatory current as well as combinations of two of these varying according to time in the frequency spectrum.

In the embodiment according to FIG. 4, the electrodes are effected as cable sections and divided into several segments offset to each other. The active area is decoupled from the supply area by a shielding. Several electrodes are positioned in such a way that active areas ensue in succession and cover a related area. The electrodes en masse form a closed construction within themselves, preferably in the form of one single cable.

In the embodiment according to FIG. 5, the active area of the electrodes is formed in such a way that the shield cables to other electrodes do not cover this area. Preferably by the spiral-shaped wrapping of the additionally isolated shield structure with the electrode.

In the embodiments according to FIGS. 6 and 7, the electrode and the shielded lead are effected as a flat conductor, in a preferably flexible embodiment. The shielding can be effected unilaterally or bilaterally with an internal electrode. Several electrodes and shields can be installed inside a flat twin cable. The electrodes can be transmitters, receivers or a measuring point.

In the embodiment according to FIG. 8, the electrodes run across the corner region of a vehicle window. In the embodiment shown here the window is bordered by four electrodes, each running across the corner region. These electrodes are symmetrically arranged inside a secured edge. Preferably, the electrodes are symmetrically arranged in such a way that interruptions act upon (at least two) electrodes simultaneously and the interruptions can be excluded.

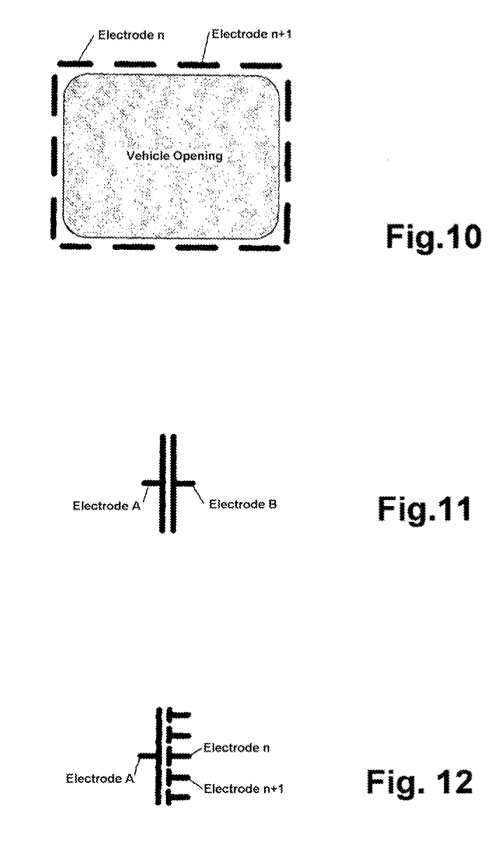

In the embodiments according to FIGS. 9 and 10, the electrodes are positioned in the area of a vehicle window away from edges or positions having the danger of being jammed. The edges are safeguarded with several, preferably 4, electrodes.

In the embodiments according to the FIGS. 11 and 12, a door, a cover or a part to be otherwise secured is used as an electrode/counter-electrode. The door or cover is electrically isolated opposite the chassis. The counter-electrode can consist of one or several segments. The counter-electrode can be effected in a cable form (for variants of embodiments see FIGS. 1-7). The chassis can serve as a counter-electrode or a transmission medium.

General:
The electrodes/counter-electrodes can be a component of the seal between the door/cover and the chassis
The electrodes/counter-electrodes are operated in one of the sealing chambers inside the rubber-joint
A metal insert is used as an electrode/counter-electrode. The metal insert can, preferably, serve to clamp the seal to the chassis.
The electrode/counter-electrode is inserted between the seal and the chassis. Preferably in the clamping area of the seal.

1. An electrode arrangement for detecting the presence of an object in an observation area, the arrangement comprising:
an electrode device for issuing or detecting an alternating field in an issuing zone,
an electronic circuit for charging the electrode device with an alternating voltage or for detecting a voltage adjacent the electrode device,
a connecting cable for connecting the electrode device to the electronic circuit,
a shield device for shielding the connecting cable, and
an electrode checking device for generating an indicative signal with regard to the electric continuity of the electrode device.

2. The electrode arrangement according to claim 1 wherein the electric continuity of the electrode device is determined by a measurement of the elapsed time or the signal reflection.

3. The electrode arrangement according to claim 1 wherein the electrode device comprises an up-and-down line section, and that the electric continuity of the electrode device is detected by a circuit including the up-and-down line section.

4. The electrode arrangement according to claim 3 wherein a terminator circuit is supplied in a transient area between the up-and-down line section.

5. The electrode arrangement according to claim 4 wherein the up-and-down line sections are directly connectable with each other via the terminator circuit.

6. An electrode arrangement for detecting the presence of an object in an observation area, the arrangement comprising:
an electrode device for issuing an alternating field into an issuing zone,
an electronic circuit for the electric continuity of the electrode device with an alternating voltage, the electrode device comprising several transmission electrode sections each attached to the electronic circuit via a connecting cable, the connecting cables each being provided with a shield and with transmission electrode sections exposed in a staggered way.

7. The electrode arrangement according to claim 6 wherein the transmission electrode sections are effected as electrode wires.

8. The electrode arrangement according to claim 7 wherein the electrode wire of the respective transmission electrode section is wound around the shield of the subsequent transmission electrode section.

9. The electrode arrangement according to one of the claims 6 wherein the electrode sections and the shields are formed as a cable structure.

10. An electrode arrangement for detecting the presence of an object in an observation area, the arrangement comprising:
an electrode device for issuing an alternating field into an issuing zone,
an electronic circuit for charging the electrode device with an alternating voltage,
a connecting cable for connecting the electrode device to the electronic circuit, and
a shield device for shielding the connecting cable, the electrode device and the shield device being flat conductor structures.

11. The electrode arrangement according to claim 10 wherein the electrode device is a conductive structure of varnish.

12. The electrode arrangement according to claim 10 wherein the shield device is a conductive structure of varnish.

13. The electrode arrangement according to claim 10 wherein the electrode device is a conductive metal film structure.

14. The electrode arrangement according to claim 10 wherein the shield device is a conductive metal film structure.
